(19) United States
(12) Patent Application Publication
(10) Pub. No.: US 2017/0253992 A1
(43) Pub. Date: Sep. 7, 2017

(54) Stable P-Type Zinc Oxide and Bandgap Engineered Zinc Oxide and Other Oxide Systems

(71) Applicant: Eric A Burgett, Pocatello, ID (US)

(72) Inventor: Eric A Burgett, Pocatello, ID (US)

(21) Appl. No.: 15/446,418

(22) Filed: Mar. 1, 2017

Related U.S. Application Data
(60) Provisional application No. 62/301,738, filed on Mar. 1, 2016.

(51) Int. Cl. C30B 25/16; H01L 21/687; C30B 25/18; C23C 16/458; C30B 25/14; C30B 29/16; C23C 16/40; H01L 21/02; C30B 25/12

(52) U.S. Cl. CPC C30B 25/165; H01L 21/02554; H01L 21/02661; H01L 21/0262; H01L 21/02403; H01L 21/02389; H01L 21/02392; H01L 21/02395; H01L 21/02398; H01L 21/02406; H01L 21/0242; H01L 21/02422; H01L 21/02414; H01L 21/02378; H01L 21/68764; C30B 25/186; C30B 25/12; C30B 25/14; C30B 29/16; C23C 16/407; C23C 16/4584

(57) ABSTRACT

Zinc oxide (ZnO) inherently exhibits n-type behavior due to naturally-occurring oxygen vacancies and zinc interstitials. Many other metal oxide systems have been found to exhibit similar semiconductor characteristics as zinc oxide, i.e. inherently n-type, including other metal oxide semiconductors such as GaO, MgO, CuO, etc. or ternary alloys with zinc oxide such as MgZnO, CdZnO, GaZnO, etc. The method described herein creates stable p-type ZnO or other metal oxide semiconductor materials, by using an oxygen scavenger material, e.g. calcium or tungsten, that is introduced during the formation of the material which preferentially scavenges oxygen resulting in an abundance of zinc vacancies, which act as holes, and induces stable p-type behavior without alloying or being incorporated into the semiconductor material itself. Three deposition techniques to deposit this stable form of p-type material and p+ type material are described.

### BACKGROUND OF THE INVENTION

Zinc oxide (ZnO) has long been studied for numerous applications due to its wide bandgap semiconductor properties and other inherent characteristics. e.g. high electron mobility. As a straight binary semiconductor material with a direct bandgap of about 3.37 electron volts (eV), ZnO potentially offers many important and unique solutions in the areas of: lighting (e.g. ultraviolet (UV), laser diodes (LD), UV light-emitting diodes (LED). UV-pumped phosphor-coated LEDs that produce visible light); sensors (e.g. radiation sensors, ultraviolet light sensors, and “solar-blind” light sensors); electronics (e.g. terahertz oscillators); power electronics and power devices; and piezoelectric-based electronics. With the larger bandgap, larger operating voltages within a single device can be achieved as compared to other devices that are made from silicon or its current market counterparts.

For years, this promising potential has remained largely untapped. While naturally n-type zinc oxide semiconductor materials have been studied, the inability to create stable p-type behavior has stymied the development of these applications. This invention outlines a method to fabricate a stable p-type ZnO semiconductor material while also maintaining its inherent wide bandgap and other beneficial characteristics and allowing for bandgap engineering of the material.

With the introduction of bandgap engineering, the bandgap of a ZnO ternary semiconductor can be tailored to achieve a band gap range from 1.7 to over 6.0 eV. This process and the resulting products allow for shifting the emission wavelength of LD and LED and the range of sensitivity of related ZnO sensors, potentially creating additional useful applications.

Grown zinc oxide semiconductors are inherently an n-type semiconductor material due to naturally-occurring oxygen vacancies and zinc interstitials. Fabrication of functional binary ZnO semiconductor diode structures and their derivatives has been limited due to the inability to achieve p-type behavior that is stable for long periods of time in an ambient atmosphere.

To circumvent this challenge many researchers have utilized other p-type wurtzite materials to create multi-material hetero-junctions to harness zinc oxide's wide bandgap and its other inherent semiconductor characteristics (e.g. high electron mobility). Examples of this include gallium nitride (GaN) grown on, or used as a template with, ZnO. However, the use of multi-material hetero-junctions limits the electric field and current that can be passed through the semiconductor due to differences in the crystal structural spacing (e.g. lattice mismatch) and interfacial electrical resistance.

These defects result in high leakage currents as well as high interface resistances between the hetero-layers and high resistive heating in the device. This in turn reduces operable power densities and functional currents that can be driven through the device; reduces optical and electrical efficiencies; and results in higher operating temperatures. The higher device temperatures also result in higher mobility of the elemental species in the binary constituents of the multi-material hetero-junctions that leads to eventual passivation and/or failure of the device.

Other methods to create stable p-type ZnO have included doping with other elements like lithium and hydrogen. However, the use of these materials to create ternary or higher systems with ZnO leads to the creation of deep acceptor sites within the material that result in lower majority- and minority-carrier mobility lifetimes, higher electron and hole trapping, lower device efficiency, and eventual device breakdown/passivation.

The present method for the creation of stable p-type zinc oxide uses a third material introduced during the formation of the ZnO semiconductor material which preferentially scavenges oxygen from the ZnO system resulting in an abundance of zinc vacancies, which act as holes that induce p-type behavior in the resulting material. This third material does not integrate or incorporate into the semiconductor material resulting in a semiconductor grade ZnO, which is a binary semiconductor.

The technique herein has been shown to produce stable p-type ZnO with elevated electron and hole mobilities, but without inherent deep acceptor defects. In this way it is superior to other dopant techniques which utilize Group I and Group V elements (e.g. lithium, sodium, potassium, nitrogen, phosphorus, and arsenic). Previous examples of patents which have claimed stable P-type behavior often passivate over the course of 1-18 months due to oxygen ingress, hydrogen egress, lithium mobility at room and elevated temperatures, and passivation (cluster formation) around the group I and group V elements.

P-type materials produced using the technique described in this patent have demonstrated stability in a standard temperature and pressure (STP) ambient atmosphere environment in excess of 24 months.

The present technique has been applied using Chemical Vapor Deposition (CVD) techniques, including Metal Organic Chemical Vapor Deposition (MOCVD), as well as Physical Vapor Deposition (PVD). i.e. thermal and electron-beam evaporation techniques.

Using the present technique, zinc oxide semiconductor devices can be fabricated consisting of both n-type and p-type ZnO materials. Having a simple method to fabricate both n-type and p-type materials from the same source materials and that share important physical and chemical characteristics would improve the economics and of ease semiconductor device fabrication as well as enable the use of zinc oxide's inherent characteristics, e.g. wide bandgap, high electron mobility, optical transparency, and/or piezoelectric effect. Such devices would also have lower threading dislocations, lower internal resistive heating, improved optical out-coupling, improved turn on voltages, higher power densities, and still possess longer operational lifetimes in a variety of operating and environmental conditions.

Semiconductor devices can also be fabricated using stable p-type ZnO overlaid on other semiconductor or conductor/conductive substrate materials, e.g., gallium nitride (GaN), Boron Nitride (BN), Aluminum Nitride (AlN), Gallium Phosphide (GaP), Gallium Arsenide (GaAs), Gallium Antimonide (GaSb), Indium Nitride (InN), Indium Phosphide (InP), Indium Arsenide (InAs), Cadmium Sulfide (CdS). Zinc Sulfide (ZnS), Titanium Oxide (TiO₂), Cupric Oxide (CuO, Cu2O), Uranium oxide (UO₂) sapphire (Al₂O₃), quartz (SiO₂), gallium oxide (GaO), organic semiconductor materials (PEDOT, Anthracene, pentacene), Indium Tin Oxide (ITO). Silicon Carbide (SiC), or others as this list is not exhaustive, to create useful semiconductor material systems.

### BRIEF SUMMARY OF THE INVENTION

The method to achieve stable p-type ZnO consists of the deposition of ZnO onto a suitable substrate through CVD or PVD processes while oxygen is scavenged from the ZnO during deposition, thus minimizing the number of resulting zinc interstitials and preventing the creation of deep-level acceptor sites.

During the vapor deposition process, an oxygen scavenging material, e.g. calcium or tungsten, is introduced along with the zinc and oxygen precursors. The oxygen scavenging material preferentially reacts with some of the oxygen precursor to create a by-product metal oxide, e.g. calcium oxide or tungsten oxide. Additionally, the growth temperature of the substrate is kept below the alloying temperature of the metal oxide/ZnO system. This causes the by-product metal oxide, e.g., calcium oxide or tungsten oxide, which has scavenged some of the oxygen precursor, to not adhere to the substrate surface and/or spall from the substrate surface, effectively removing it from the resulting semiconductor material system.

At the same time, the flow rate of the zinc precursor is reduced from the level normally used to achieve n-type ZnO. Normal n-type ZnO can be characterized as having a number of oxygen vacancies (x) and a different number of zinc interstitials (y). The present technique simultaneously lowers the number of zinc interstitials (y−a) (where a is a small number of zinc interstitials controlled by the fabrication process) while simultaneously increasing the number of oxygen vacancies (x+b) (where b is a small number of oxygen vacancies also controlled by the fabrication process). Because the relative abundance of oxygen vacancies are not filled with zinc interstitials, as would normally occur during fabrication under conditions suitable to achieve n-type zinc oxide, the resulting unfilled oxygen vacancies act as holes that induce p-type behavior in the resulting material. The result is a stable p-type ZnO material with increased oxygen vacancies and reduced zinc interstitials. By controlling the fabricating conditions and amount of oxygen scavenging material introduced, different values can be obtained for a and b which results in variations of the p-type characteristics of the fabricated ZnO system. Variations of p-type characteristics that can be controlled through the growth process include changes in hole densities and electron densities and hole and electron mobilities. These variations can also affect bulk resistivity, sheet resistivity, interface resistance, and electrical contact resistance of a semiconductor device fabricated from the p-type material.

The oxygen scavenging material needs to have a higher affinity for oxygen than zinc. Materials that have been successfully used include calcium and tungsten. Other materials that could be used include, for example, copper, tin, thorium, and uranium.

This new method for the creation of stable p-type ZnO reduces the flow rate of the zinc precursor from the level normally used to fabricate n-type ZnO during the formation of the semiconductor material. By decreasing the zinc precursor flow rate, the number of zinc interstitials also decreases in the ZnO system. The zinc interstitials, when present, act as donors; with the increase in oxygen vacancies and simultaneously limiting the zinc interstitials, the increased vacancies act as holes, helping induce stable p-type behavior in the resulting material.

Bandgap-engineered ternary ZnO semiconductor systems such as CoZnO, CdZnO, MgZnO. GaZnO and others can be fabricated using a similar growth technique to undoped ZnO. Using a similar process to the method described above, the alloying agent e.g. Co, Cd, Mg, etc. is allowed to alloy during growth while the oxygen scavenging behaves as described above. In this case, since the alloying agent requires a hotter deposition temperature, the oxygen scavenging agent should have a higher solidification temperature, allowing it to spall off the hotter surface. The oxygen scavenger in this instance should be a high refractory temperature metal whose oxide form has a very high melting point e.g. tungsten, uranium, thorium, etc. As with the ZnO binary system, the oxygen scavenger precursor, e.g., tungsten, that is introduced during growth process does not adhere to or become incorporated into the bandgap engineered material. The scavenger material is allowed to spall from the surface, the result of which does not introduce added donor sites or produce shallow trap sites.

Provided herein are examples for the ZnO and alloyed zinc oxide systems. This technique can also be applied to other binary metal oxide systems such as GaO, MgO, CuO, and others to create stable p-type behavior.

In this document, the notion of stability is defined as maintaining operational characteristics (p-type behavior) for a period of greater than 24 months in an ambient STP atmosphere. Stability also implies a temperature of active operation of devices at temperatures in excess of 400 C for extended periods of time.

### BRIEF DESCRIPTION OF THE DRAWINGS

FIG. 1: n contact, n, p, p contact device

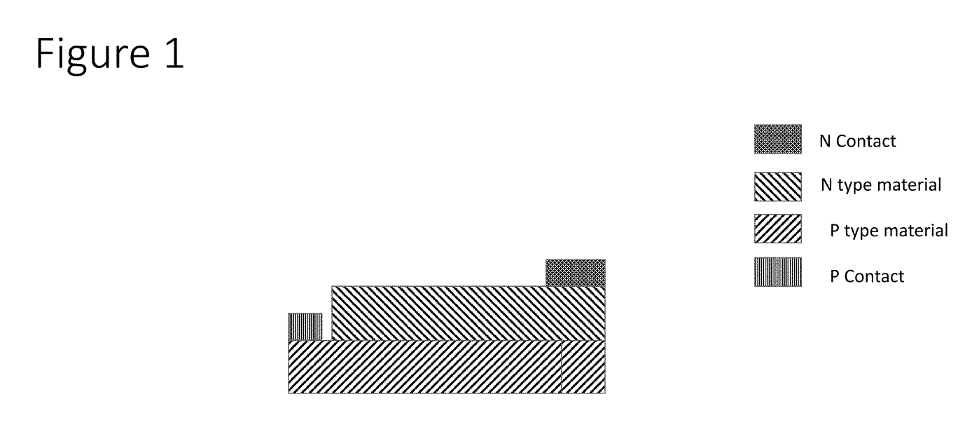

FIG. 2: n contact, n−, n, p, p+, p contact device needs to be shown.

FIG. 3, n contact, n, p, n, contacts shown

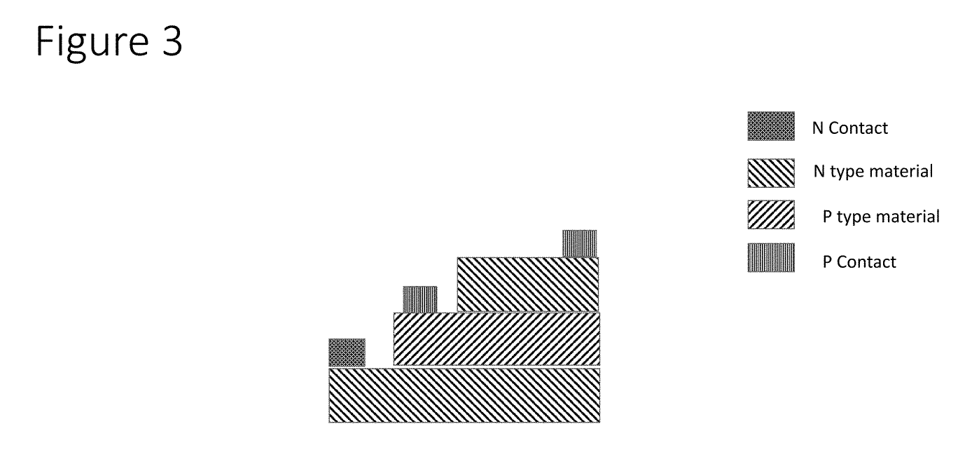

FIG. 4 p contact, p, n, p, contacts shown

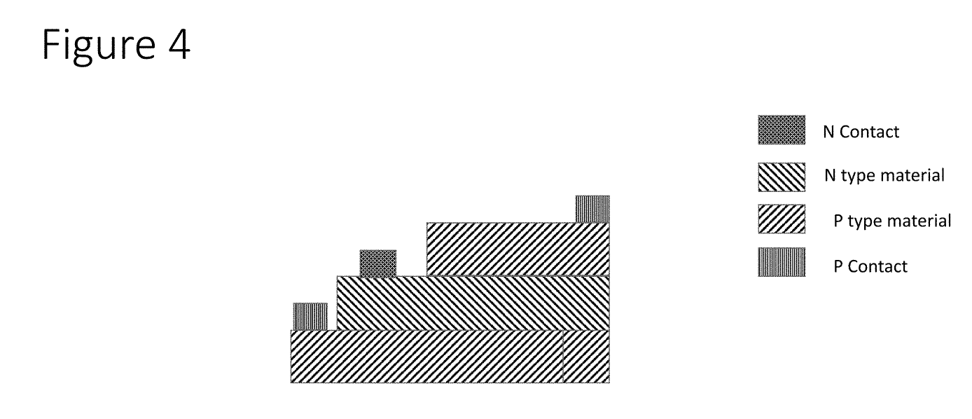

### DETAILED DESCRIPTION OF THE INVENTION

In this invention, the fundamental differentiator to other p-type dopant patents is that in previous patents, oxygen concentrations and dopant oxide clusters form the holes necessary to create the p-type behavior which is a critical component to creating a semiconductor junction. These clusters are inherently unstable and often passivate and/or diffuse, destroying the semiconductor material junction's properties. Unlike previous techniques, this technique allows for the formation of oxygen depleted ZnO, which exhibits stable p-type behavior, without the addition of other impurities and while maintaining the stable crystalline structure. When layered or formed onto natural or doped n-type zinc oxide, a stable PN or NP junction can be formed.

Traditional dopants are alloyed in, forming a uniform dispersion of vacancies or interstitial insertions into the crystalline lattice. These can be in the form of substitutional replacements, interstitials, a vacancy, or a filled vacancy. These can often lead to strain in the surrounding atoms in the crystalline lattice which can enhance the p-type behavior. However, these strain centers often lead to enhanced mobilities of other elemental species. This added mobility leads to the early passivation of the dopant centers in previous dopant based p-type solutions. This undesirable effect is further enhanced at elevated temperatures. This leads to layer passivation and eventual device failure.

To achieve stable p-type zinc oxide material, two growth techniques are defined below. The first is through Physical Vapor Deposition (PVD) and the second is through Low Pressure Rotating Disc (LPRD) Metal Organic Chemical Vapor Deposition (MOCVD).

### Physical Vapor Deposition to Achieve Stable P-Type ZnO

To prepare the sample for deposition of a p-type material, the substrate material should be cleaned to allow for low interface resistance between layers. This cleaning technique can be any number of the following processes: ultrasonic cleaning; reactive ion-etching; plasma enhanced ion etching; plasma enhanced reactive ion etching; acid etching; plasma cleaning using O₂, Ar, CH₂, C₂H₂, CF₄, CF₃H, or the like; plasma ashing/etching; ion milling; glancing angle ion milling; mechanical lapping/polishing; rapid thermal annealing in reactive or inert atmosphere; rapid thermal annealing in a hydrogen or vacuum atmosphere; or other.

The purpose of this cleaning is to remove any extra oxygen that is entrained at the substrate surface prior to application of the p-type material. This impurity layer, which may be only an atom layer thick to several microns thick depending on the age of the sample, would interfere with the transmission of electron and/or hole centers into and out of the p-type layer. The extra oxygen and hole density due to this layer can also diffuse into the deposited p-type layer and can lead to premature passivation. The previous steps are best performed in a chamber which is maintained at vacuum between the cleaning and the deposition of the p-type materials. If the cleaning step is not integrated into the same chamber as the following step, care should be taken to protect the substrate surface with a coating or other technique to prevent excess oxygen ingress into the substrate surface.

The substrate on which the p-type layer is to be deposited, which has been cleaned, is mounted above a deposition source. This mounting is usually in a fixturing device which allows for rotation of the sample with respect to the deposition source below.

The p-type precursor material is placed in a thermal heating hearth, boat, crucible, or other heating device below the substrate.

The p-type precursor materials are prepared and deposition source fabricated and readied for the PVD process as described in sections [104 to 114].

In the PVD processing and fabrication of stable P-type ZnO first the PVD chamber is evacuated.

A base pressure of 10⁻⁴ to 10⁻⁹ torr is obtained and maintained inside the chamber.

If a coating has been applied to the surface to prevent oxygen ingress, at this point it should be removed through heating, sublimation, etching or other technique as needed.

An in-situ film thickness monitor is turned on at this point and allowed to stabilize.

If a substrate heater is necessary (e.g., as needed for SiO₂, ZnO, GaN, GaO, Al₂O₃, and other crystalline substrates), it is now energized and allowed to stabilize.

### Heating the PVD Precursor

Due to the powdered nature of the precursor material, the precursor is slowly heated, allowing the material to offgas several times prior to sublimation temperature and pressure is obtained. As the sample warms up, the base pressure will rise. During this time period, the heating power applied to the sample is reduced and the base pressure vacuum is allowed to return to the lower pre-prescribed pressure.

The process described above in paragraph 39 is repeated cyclically until all of the excess air which is entrained in the sample is removed. As the temperature of the deposition material is increased, the base pressure will stabilize. When the pressure has been stabilized, heating power is continually increased until the sample begins to sublimate.

### Depositing the Material

As the precursor material reaches deposition temperature (the precise sublimation temperature depends on chamber base pressure) the heating power is accelerated until a jump followed by a steep drop in base pressure is observed. At this point the scavenger material is preferentially attacking the sublimating zinc oxide elemental stream stripping and liberating oxygen from the zinc oxide and forming a stable solid oxide of the refractory metal while continuing to deposit semiconductor grade zinc oxide onto the substrate. The jump in base pressure is caused by the conversion of molecular zinc oxide into two or more molecules (zinc and free oxygen) which usually recombine on the substrate surface. The precipitous drop in base pressure is the result of preferential scavenging of the resultant free oxygen available in the system.

Deposition continues until the desired layer thickness is achieved. Precursor materials (zinc oxide and oxygen scavenger) can be supplied as needed to achieve the desired layer thickness.

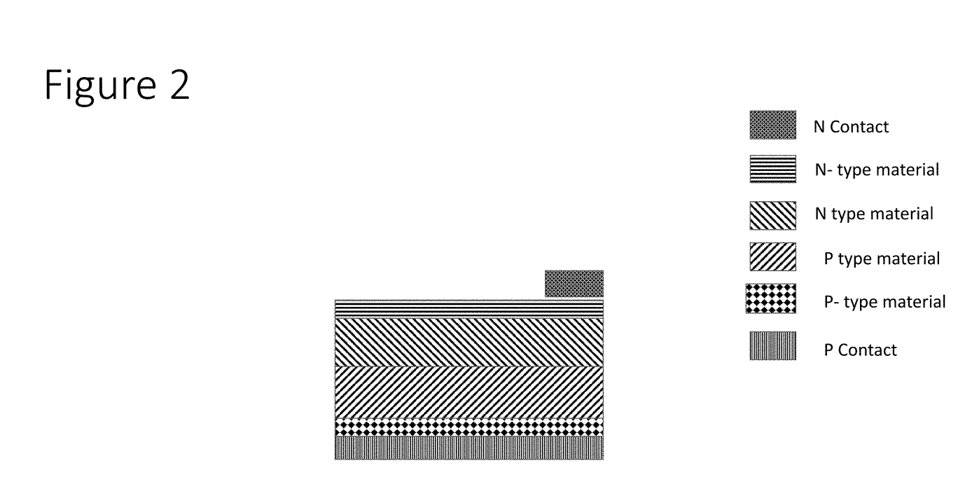

To fabricate a functional semiconductor device, like the one seen in FIG. 2, it is often required to prepare the surface to support the application of a highly doped p-type layer (p+ layer) prior to the deposition of electrical contacts. This p+ layer produces an enhanced blocking effect in the junction resulting in higher blocking voltages being able to be achieved. To achieve this, a second mixture of source materials, prepared in a similar fashion to the first with a higher refractory metal concentration is utilized for this process. A parallel co-deposition or sequential deposition scheme is used to create this heterostructure. The parallel co-deposition technique is preferred over the sequential growth due to the smooth transition in layer types and resulting hole densities in the device as opposed to an abrupt change in these parameters resulting in increased interface resistances.

The second mixture is heated in a process following the procedure listed above in section 38 and raised to the deposition temperature described above in section 40.

The deposition continues until a p+ layer thickness of 10-100 nanometers (nm) is applied.

The p+ layer is more sensitive to oxygen damage and oxygen ingress. As such, two means of protection of this layer are provided for:

a. Deposition of a protection cap layer; and

b. Deposition of an oxygen scavenger layer.

Deposition of a protection cap layer is accomplished through a subsequent sequential capping layer of a protective oxide or nitride material such as Al₂O₃. This is accomplished using standard PVD deposition techniques.

Deposition of a sacrificial oxygen scavenger layer is accomplished through the heating of a refractory metal for deposition in the chamber, such as calcium, tungsten, strontium, erbium, aluminum, titanium, uranium, or thorium. During the deposition process, a high frequency glow discharge or surface reactant flow gas is employed to further strip oxygen from the scavenger layer. This gas is a highly reactive gas such as ammonia, hydrogen, hydrazine or the like. This is required since the metals to be deposited inherently have trapped or entrained oxygen which will have a propensity to migrate into the p+ layer.

Glow discharge is accomplished through the introduction of a high frequency RF, high voltage low current power source between the base plate (evaporant) and the substrate and substrate fixturing.

Surface reactant flow gas is a gas that is heated and flowed across the surface of the substrate with a flow rate low enough to maintain a laminar flow regime over the entire substrate while not obstructing the deposition of the hot gas molecules emanating from the source below.

The scavenger layer is preferably capped by a protective noble metal layer such as gold, platinum, or the like. This layer is deposited using a standard physical vapor deposition technique.

Once the protective layer has been applied, the chamber, substrate, and remaining deposition materials are allowed to cool to ambient temperature.

Nitrogen or argon gas are re-introduced to the high vacuum chamber and the sample can be removed from the chamber.

Normal patterning, etching, contact deposition, bonding and other processes can be subsequently carried out. Wet deposition techniques should be avoided, rather dry reactive ion etching processes or plasma enhanced dry reactive ion etching processes should be employed for etching of the substrates. Aqueous water will accelerate the deterioration of the p+ and p layer electrical behaviors.

### Metal Organic Chemical Vapor Deposition to Achieve Stable P-Type ZnO

To prepare the sample for deposition of a p-type material, the substrate material is preferably cleaned to allow for low interface resistance between layers. This cleaning technique can be any number of the following processes: ultrasonic cleaning; reactive ion-etching; plasma enhanced ion etching; plasma enhanced reactive ion etching; acid etching; plasma cleaning using O₂, Ar, CH₂, C₂H₂, CF₄, CF₃H, or the like; plasma ashing/etching; ion milling; glancing angle ion milling; mechanical lapping/polishing; rapid thermal annealing in reactive or inert atmosphere; rapid thermal annealing in a hydrogen or vacuum atmosphere; or other.

The purpose of this cleaning is to remove any extra oxygen which inherently is entrained at the substrate surface prior to application of the p-type material. This impurity layer, which may be only an atom layer thick to several microns thick depending on the age of the sample, would interfere with the transmission of electron and/or hole centers into and out of the p-type layer. The extra oxygen and hole density due to this layer can also diffuse into the deposited p-type layer and can lead to premature passivation. The previous steps are best performed in a chamber which is maintained at vacuum between the cleaning and the deposition of the p-type materials. If the cleaning step is not integrated into the same chamber as the following step, care should be taken to protect the substrate surface with a coating or other technique to prevent excess oxygen ingress into the substrate layers.

If the p-type layer is to be deposited onto a n-type layer, a smooth transition from n-type material to p-type material is desirable and the growth temperature, rotation speed, precursor flow rates used to build the n-type layer should all be maintained to prevent strain and interfacial layer insulation forming between the grown/deposited layers.

Prior to the beginning of growth of the p-type layer, a brief pulse of anhydrous ammonia, hydrogen, or hydrazine should be applied at the growth temperature to clean the surface of the substrate and remove any extra oxygen which is entrained in or attached to the surface of the substrate.

Growth of the p-type layer should commence as quickly as possible after the ammonia, hydrogen, or hydrazine pulse is completed.

The growth of p-type material using low pressure rotating disk (LPRD) metal organic chemical vapor deposition (MOCVD) can be done in two modalities: continuous flow MOCVD growth and pulsed MOCVD growth with pulsed growth performing better than that of continuous flow mode.

### Continuous Flow MOCVD Growth

To prepare for growth, the chamber base pressure is set to 1-100 torr. The rotation speed is selected based on the size of the chamber and required total flow rate to maintain laminar flow over the platter and substrates. Temperature is set to between 100-800 C depending on the binary or ternary mix of materials which is being used as precursors.

All precursors are of semiconductor grade, at least 99.999% purities.

The zinc precursor used can be: diethylzinc, dimethylzinc, CP2Zinc, bis(tetramethyl-heptanedionato)zinc [Zn(TMHD)2], bis(trifluoro-thienyl-butanedionato) zinc [TMEDA], diphenylzinc, bis(pentafluorophenyl)zinc, or other CVD zinc precursor.

The oxygen precursor is either oxygen gas, nitrous oxide, or water.

The refractory metal precursors can be:
a. calcium, including: bis(heptafluoro-dimethyl-octanedionate)calcium [Ca(FOD)2], bis(tetramethyl-heptanedionato)calcium [Ca(TMHD)2], calcium hexafluoroacetylacetonate dihydrate, or other CVD calcium precursor;
b. titanium, including: tetrakis(ethylmethylamino)titanium, tetrakis(dimethylamino)titanium(IV) (TDMAT), titanium(IV) isopropoxide, cyclopentadienyl(cycloheptatrienyl)titanium(II), pentamethylcyclopentadienyltris(dimethylamino)titanium(IV), tetrakis(diethylamino)titanium(IV), titanium(IV) diisopropoxidebis(tetramethyl-heptanedionate), titanium(IV) n-butoxide, titanium(IV) t-butoxide, titanium(IV) chloride, titanium(IV) (di-i-propoxide)bis, titanium(IV) ethoxide, titanium(IV) i-propoxide, (trimethyl)pentamethylcyclopentadienyltitanium(IV), tris(tetramethyl-heptanedionato)titanium(III) [Ti(TMHD)3], titanium tetrachloride, or other CVD titanium precursor;
c. tungsten including: bis(t-butylimido)bis(dimethylamino)tungsten(VI) [BTBMW], mesitylene tungsten tricarbonyl, tungsten carbonyl, tungsten(VI) oxychloride, bis(cyclopentadienyl)tungsten(IV) dichloride, bis(cyclopentadienyl)tungsten(IV) dihydride, bis(isopropylcyclopentadienyl)tungsten(IV) dihydride, cyclopentadienyltungsten(II) tricarbonyl hydride, tungsten hexacarbonyl, bis(butylcyclopentadienyl)tungsten(IV) diiodide, bis(tert-butylimino)bis(tert-butylamino)tungsten, bis(tert-butylimino)bis(dimethylamino)tungsten(VI), triamminetungsten(IV) tricarbonyl, or other CVD tungsten precursor.

### Growth of P-Type ZnO by Continuous Flow LPRDMOCVD

Growth commences and flow rates of the zinc and oxygen precursor are balanced as before for the growth of n-type zinc oxide. The refractory metal precursor flow is commenced at a rate of up to 10 percent of the zinc precursor flow rate. The oxygen flow rates are slightly decreased (up to 1 percent reduction as compared with normal n-type growth flow rate). The zinc precursor and oxygen precursor flow rates are decreased based on the specific tool, flow rate, and base pressure, and refractory metal selection.

Flow rates are set for diluent gas (e.g. nitrogen, argon, etc) flow rates relative to the zinc precursor and refractory metal precursor flow rates based on precursor selection and desired growth rate. The ratio of mass flow rate of the refractory metal in the metal organic should be less than 10 percent of that of the metal mass flow rate in the zinc precursor and set such that the unintentional alloying is minimized.

In-Situ reflectance high energy electron diffractometry (RHEED), as well as surface ellipsometry, laser interferometry, and other online film thickness and film quality diagnostics are utilized to maintain high quality growth and measure deposition rate and deposition thickness.

Growth is stopped at a thickness between 10 and 500 nm.

To fabricate a functional semiconductor device, like the one seen in FIG. 2, it is often required to prepare the surface to support the application of a highly doped p-type layer (p+ layer) prior to the deposition of electrical contacts. This p+ layer produces an enhanced blocking effect in the junction resulting in higher blocking voltages being able to be achieved. To achieve this, a second dopant concentration flow rate of source materials, grown in a similar fashion to the first with a higher refractory metal concentration is utilized for this process. A smooth ramp transition in the source precursor flow rates allows for a smooth transition using a sequential deposition scheme to create this heterostructure. This results in a smooth transition in layer types and resulting hole densities in the device as opposed to an abrupt change in these parameters resulting in increased interface resistances if an abrupt sequential transition is employed.

To deposit the p+ layer, a similar growth recipe is followed as above as in section 66. Growth commences and flow rates of the zinc and oxygen precursor are balanced as before for the growth of n-type zinc oxide. The refractory metal precursor flow is commenced at a ratio of up to 18 percent of the zinc precursor. The oxygen flow rates are slightly decreased (up to 2 percent reduction). The zinc precursor and oxygen precursor flow rates are decreased based on the specific tool, flow rate, and base pressure, and refractory metal selection. The transition from the previous flow rates of refractory metal of 10 percent with respect to zinc and 1 percent reduction in oxygen relative to n-type growth, to the 18 percent and 2 percent listed above to achieve the p+ layer should be made in a smooth, continuously changing distribution to provide a gradual ramp in dopant densities.

Flow rates are set as well as dilutant gas flow rates to the zinc precursor and refractory metal precursor based on precursor selection and desired growth rate. The ratio of mass flow rate of the refractory metal in the metal organic should be less than 18 percent of that of the metal mass flow rate in the zinc precursor and set such that the unintentional alloying is minimized.

In-Situ reflectance high energy electron diffractometry (RHEED), as well as surface ellipsometry, laser interferometry, and other online film thickness diagnostics and film quality diagnostics are utilized to maintain high quality growth and measure deposition rate and deposition thickness.

Growth is stopped at a thickness between 10-50 nm.

The p+ layer is more sensitive to oxygen damage and oxygen ingress. As such, two means of protection of this layer are provided for:

a. Deposition of a protection cap layer; and

b. Deposition of an oxygen scavenger layer.

Deposition of a protection cap layer is accomplished through a subsequent sequential capping layer of a protective oxide or nitride material, such as Al₂O₃.

To deposit the protective cap layer, a recipe is loaded for a cold (less than 200 C) growth temperature growth of sapphire (Al₂O₃), conductive indium tin oxide (ITO), gallium oxide (GaO), gallium-doped zinc oxide (Ga:ZnO), or other material. In all of these materials the oxygen precursor is decreased from the normal growth regime by 2-5 percent depending on the chamber and pressure for the growth. Growth is conducted in the normal fashion otherwise.

Deposition of a sacrificial oxygen scavenger layer is accomplished through the deposition of a scavenger material without removing the sample from the chamber, such as calcium, tungsten, strontium, erbium, aluminum, titanium, thorium, or uranium. During the deposition process, a surface reactant flow gas is employed to further strip oxygen from the scavenger layer. This gas is a highly reactive gas such as ammonia, hydrogen, hydrazine or the like. Oxygen precursor gas is not flowed during this process. Nitrogen-based precursors are employed during this deposition to minimize excess oxygen to prevent this deposited layer from inherently possessing trapped or entrained oxygen which will have a propensity to migrate into the p+ layer.

Surface reactant flow gas is a gas which is heated and flowed across the surface of the substrate with a flow rate to maintain a laminar flow regime over the entire substrate while not obstructing the deposition of the process gas which is flowing from the shower head above.

The scavenger layer is required to be capped by a protective noble metal layer such as gold, platinum, or the like. This layer is deposited in a standard chemical vapor deposition technique.

Once the protective layer has been applied, the chamber, substrate, and remaining deposition materials are allowed to cool to ambient temperature.

Nitrogen or argon gas are re-introduced to the high vacuum chamber and the sample can be removed from the chamber.

Normal patterning, etching, contact deposition, bonding and other processes are subsequently carried out. Wet deposition techniques should be avoided, rather dry reactive ion etching processes or plasma enhanced dry reactive ion etching processes should be employed for etching of the substrates. Aqueous water will accelerate the deterioration of the p+ and p layer electrical behaviors.

### Pulsed MOCVD Growth

Pulsed growth is superior to continuous growth and is used more frequently. It is only possible using a fast acting low pressure rotating disk (LPRD) metal organic chemical vapor deposition (MOCVD) tool with response times and solenoid valve action times and system automation response times faster than 10 milliseconds (ms).

Unlike traditional continuous flow LPRD MOCVD, the pulsed growth technique minimizes the unintentional doping of the sample during growth. This creates a higher quality, lower impurity semiconductor material.

To prepare for growth, the chamber base pressure is set to 1-100 torr. The rotation speed is selected based on the size of the chamber and required total flow rate to maintain laminar flow over the platter and substrates. Temperature is set to between 100 and 800 C depending on the binary or ternary mix of materials which is being used as precursors.

All precursors are of semiconductor grade, at least 99.999 percent purities.

The zinc precursor used can be: diethylzinc, dimethylzinc, CP2Zinc, bis(tetramethyl-heptanedionato)zinc [Zn(TMHD)2], bis(trifluoro-thienyl-butanedionato) zinc [TMEDA], diphenylzinc, bis(pentafluorophenyl)zinc, or other CVD zinc precursor.

The oxygen precursor is either oxygen gas, nitrous oxide, or water.

The refractory metal precursors can be:
a. calcium, including: bis(heptafluoro-dimethyl-octanedionate)calcium [Ca(FOD)2], bis(tetramethyl-heptanedionato)calcium [Ca(TMHD)2], calcium hexafluoroacetylacetonate dihydrate, or other CVD calcium precursor;
b. titanium, including: tetrakis(ethylmethylamino)titanium, tetrakis(dimethylamino)titanium(IV) (TDMAT), titanium(IV) isopropoxide, cyclopentadienyl(cycloheptatrienyl)titanium(II), pentamethylcyclopentadienyltris(dimethylamino)titanium(IV), tetrakis(diethylamino)titanium(IV), titanium(IV) diisopropoxidebis(tetramethyl-heptanedionate), titanium(IV) n-butoxide, titanium(IV) t-butoxide, titanium(IV) chloride, titanium(IV) (di-i-propoxide)bis, titanium(IV) ethoxide, titanium(IV) i-propoxide, (trimethyl)pentamethylcyclopentadienyltitanium(IV), tris(tetramethyl-heptanedionato)titanium(III) [Ti(TMHD)3], titanium tetrachloride, or other CVD titanium precursor;
c. tungsten including: bis(t-butylimido)bis(dimethylamino)tungsten(VI) [BTBMW], mesitylene tungsten tricarbonyl, tungsten carbonyl, tungsten(VI) oxychloride, bis(cyclopentadienyl)tungsten(IV) dichloride, bis(cyclopentadienyl)tungsten(IV) dihydride, bis(isopropylcyclopentadienyl)tungsten(IV) dihydride, cyclopentadienyltungsten(II) tricarbonyl hydride, tungsten hexacarbonyl, bis(butylcyclopentadienyl)tungsten(IV) diiodide, bis(tert-butylimino)bis(tert-butylamino)tungsten, bis(tert-butylimino)bis(dimethylamino)tungsten(VI), triamminetungsten(IV) tricarbonyl, or other CVD tungsten precursor.

A pulsed growth recipe is established and cycled recursively depositing layers of material until the desired layer thickness is achieved. In this pulsed growth regime, the metal precursor and oxygen precursor are started as step one in the cycle. The duration of this step is set to achieve about 3-100 atom layers of zinc oxide material. The exact period (time for this step in this cycle) depends on the growth rate with superior growth occurring during slower growth rates of less than 250 nm per hour.

Growth commences and flow rates of the zinc and oxygen precursor are balanced for the normal growth of n-type zinc oxide.

Following the deposition of 3-100 atoms the zinc and oxygen precursors are stopped rapidly. Simultaneously, the refractory metal precursor is pulsed on. It remains on for up to 10 percent of the zinc and oxygen precursor period. Longer durations of the refractory metal pulse time results in a higher propensity to alloy the refractory metal into the zinc oxide semiconductor. The exact flow rates and pulse durations are established based on the partial pressure of the precursor, chamber pressure, temperature of the substrate, rotation speed of the platter, and others and is therefore machine specific.

Once the refractory metal is pulsed off, a nitrogen and/or nitrogen-hydrogen pulse of up to 200 percent the normal diluent gas flow rate is started. During the flow of the refractory metal, it creates a metal oxide which is not alloyed into the semiconductor. The refractory metal oxide forms a loose oxidized powder on the surface of the semiconductor. This is due to the fact the metal oxide alloying temperature is significantly below that of the zinc oxide growth temperature. It does not have enough surface energy to adhere to the zinc layer below. However, the refractory metal material is selected with a higher affinity of oxygen than that of the zinc. It preferentially scavenges the excess interstitial oxygen from the 3-100 atom layers below from the previous pulse. The added nitrogen or nitrogen-hydrogen flow assists in removing excess oxygen, any entrained carbon (introduced by the organic nature of the precursors used), and the refractory oxide residue from the substrate; essentially blowing the oxide powder from the surface of the substrate.

Following the nitrogen or nitrogen/hydrogen pulse, zinc and oxygen precursors begin flowing again.

In-Situ reflectance high energy electron diffractometry (RHEED), as well as surface ellipsometry, laser interferometry, and other online film thickness and quality diagnostics are utilized to maintain high quality growth and measure deposition rate and deposition thickness.

Growth is stopped at a thickness between 10 and 500 nm.

To fabricate a functional semiconductor device, like the one seen in FIG. 2, it is often required to prepare the surface to support the application of a highly doped p-type layer (p+ layer) prior to the deposition of electrical contacts. This p+ layer produces an enhanced blocking effect in the junction resulting in higher blocking voltages being able to be achieved. To achieve this, a second dopant concentration flow rate of source materials, grown in a similar fashion to the first with a higher refractory metal concentration is utilized for this process. A smooth ramp transition in the source precursor flow rates allows for a smooth transition using a sequential deposition scheme to create this heterostructure. This results in a smooth transition in layer types and resulting hole densities in the device as opposed to an abrupt change in these parameters resulting in increased interface resistances if an abrupt sequential transition is employed.

To deposit the p+ layer, a similar growth recipe is followed as above. Growth commences and flow rates of the zinc and oxygen precursor are balanced as before for the growth of n-type zinc oxide. The refractory metal precursor flow is commenced at a ratio of up to 18 percent of the zinc precursor. The oxygen flow rates are slightly decreased (up to 2 percent reduction). The zinc precursor and oxygen precursor flow rates are decreased based on the specific tool, flow rate, and base pressure, and refractory metal selection. The transition from the previous flow rates of refractory metal of 10 percent with respect to zinc and 1 percent reduction in oxygen relative to p-type growth described in paragraph 93, to the 18 percent and 2 percent listed above to achieve the p+ layer should be made in a smooth, continuously changing distribution to provide a gradual ramp in dopant densities.

Flow rates are set as well as dilutant gas flow rates to the zinc precursor and refractory metal precursor based on precursor selection and desired growth rate. The ratio of mass flow rate of the refractory metal in the metal organic should be less than 18 percent of that of the metal mass flow rate in the zinc precursor and set such that the unintentional alloying is minimized.

In-Situ reflectance high energy electron diffractometry (RHEED), as well as surface ellipsometry, laser interferometry, and other online diagnostics are utilized to maintain high quality growth and measure deposition rate and deposition thickness.

Growth is stopped at a thickness between 10-50 nm.

The p+ layer is more sensitive to oxygen damage and oxygen ingress. As such, two means of protection of this layer are provided for:

a. Deposition of a protection cap layer; and

b. Deposition of an oxygen scavenger layer.

Deposition of a protection cap layer is accomplished through a subsequent sequential capping layer of a protective oxide or nitride material, such as Al₂O₃.

To deposit the protective cap layer, a recipe is loaded for a cold (less than 200 C) growth temperature growth of sapphire (Al₂O₃), conductive indium tin oxide (ITO), gallium oxide (GaO), gallium-doped zinc oxide (Ga:ZnO), or other material. In all of these materials the oxygen precursor is decreased from the normal growth regime by 2-5 percent depending on the chamber and pressure for the growth. Growth is conducted in the normal fashion otherwise.

Deposition of a sacrificial oxygen scavenger layer is accomplished through the deposition of a scavenger material without removing the sample from the chamber, such as calcium, tungsten, strontium, erbium, aluminum, titanium, thorium, or uranium. During the deposition process, a surface reactant flow gas is employed to further strip oxygen from the scavenger layer. This gas is a highly reactive gas such as ammonia, hydrogen, hydrazine or the like. Oxygen precursor gas is not flowed during this process. Nitrogen-based precursors are employed during this deposition to minimize excess oxygen to prevent this deposited layer from inherently possessing trapped or entrained oxygen which will have a propensity to migrate into the p+ layer.

Surface reactant flow gas is a gas which is heated and flowed across the surface of the substrate with a flow rate to maintain a laminar flow regime over the entire substrate while not obstructing the deposition of the process gas which is flowing from the shower head above.

The scavenger layer is required to be capped by a protective noble metal layer such as gold, platinum, or the like. This layer is deposited in a standard chemical vapor deposition technique.

### Creation of Refractory Metal Powder Precursor for Physical Vapor Deposition Technique

To create the precursor powder for physical vapor deposition, a mix of refractory metal and zinc oxide powder is uniformly homogenized and sintered into a pellet for heating and deposition. The intimate mixing of nanopowders is required to achieve the required oxygen depletion and simultaneous deposition.

The precursor refractory metal powder should be 99.999 percent purity or greater and have a particle size ranging from 5-250 nm whether fabricated using the process described below or others.

To prepare the refractory metal, a bulk granular or ingot of refractory metal of high purity (99.999 percent) is selected.

The metal is loaded into a processing chamber and is heated. With the temperature increase and/or the addition of hydrogen, the refractory metal sloughs any surface contamination oxygen and begins a transition process to a metal hydride. More specifically, the temperature is elevated and the metal powder hydrolyzes, forming a refractory metal hydride. The hydride has a different, larger crystalline structure and as such begins to form a second phase on the surface of the metal.

Following this step, the powder is iteratively metalized and reformed as refractory metal by alternating hydrogen and inert gas flows. During each subsequent cycle, the mean particle diameter decreases as the hydride layer sloughs itself from the metallic particle. In some embodiments, a vacuum can be pulled on the system to further increase the sublimation rate of the refractory metal hydride. Because the temperature of hydration and surface areas of the metal precursor varies for each batch of raw feedstock, the time required for each iteration of gas exposure will vary based on the mean rate of change in the absorption of the reactant gas by the powder. In some embodiments, this cyclical process goes on while an in-situ process monitoring capability measures porosity, mean particle diameter, mass, surface area, and surface shape. The larger number of cycles the smaller the mean particle diameter becomes.

Upon resizing the powder according to its customized purification process, the nano powder is allowed to cool and is subsequently removed from the reactor. After that, the refined powder can be further processed in subsequent steps.

The precursor zinc oxide powder should be 99.999 percent purity or greater and have a particle size ranging from 5-250 nm whether fabricated using the process described below or others.

The zinc oxide powder can be fabricated using aqueous processes as described in references 1-29. References 1-3 detail methods to produce ZnO nanoparticles using room-temperature organometallic synthesis processes. Reference 4 describes a process to produce ZnO nanoparticles using a solvothermal process using a variety of organic solvents to achieve a variety of nanoparticle morphologies. Reference 5 describes a solvothermal process using zinc acetate and ethanol that produces uniformly spherical morphology of ZnO nanoparticles. Reference 6 describes a process to create small nanoparticles of ZnO at low-temperature using an ultrasonic treatment. Reference 7 describes a process to create ZnO nanoparticles using ultrasonic treatment and a room-temperature ionic liquid. Reference 8 describes a one-step, room-temperature, mechanochemical synthesis technique. Reference 9 describes a process to create ZnO nanoparticles via the thermal decomposition of zinc particles. Reference 10 describes a hydrothermal process to create ZnO nanoparticles. Reference 11 describes a polyol-mediated precipitation process to produce polydisperse, aggregated ZnO nanocrystals. Other processes to produce nanoparticles of zinc oxide are contained in references 12-29.

The zinc oxide powder can also be fabricated from a high purity zinc powder precursor.

To prepare the zinc oxide powder, a bulk granular or ingot of zinc metal of high purity (99.999 percent) is selected.

The metal is loaded into a processing chamber and is heated. With the temperature increase and/or the addition of hydrogen, the zinc metal sloughs any surface contamination oxygen and begins a transition process to a metal hydride. More specifically, the temperature is elevated and the metal powder hydrolyzes, forming a refractory metal hydride. The hydride has a different, larger crystalline structure and as such begins to form a second phase on the surface of the metal.

Following this step, the powder is iteratively metalized and reformed as zinc metal by alternating hydrogen and inert gas flows. During each subsequent cycle, the mean particle diameter decreases as the hydride layer sloughs itself from the metallic particle. In some embodiments, a vacuum can be pulled on the system to further increase the sublimation rate of the zinc metal hydride. Because the temperature of hydration and surface areas of the metal precursor varies for each batch of raw feedstock, the time required for each iteration of gas exposure will vary based on the mean rate of change in the absorption of the reactant gas by the powder. In some embodiments, this cyclical process goes on until an in-situ process monitoring capability measures porosity, mean particle diameter, mass, surface area, and surface shape. The larger number of cycles the smaller the mean particle diameter becomes.

The zinc nanometal powder is now flowed through a fluidized bed with a diluent gas such as argon while remaining at a high temperature. Oxygen partial pressure is increased into the argon flow rate with temperatures above 300 C. The oxygen flow rate is increased to up to 5 percent the total flow rate. The metallic particles, suspended in the fluidized bed oxidize rapidly converting to wurtzite zinc oxide nanoparticles.

Upon resizing the powder according to its customized oxidation process, the zinc nanopowder is allowed to cool and is subsequently removed from the reactor. After that, the refined powder can be further processed in subsequent steps.

The zinc and refractory metal nanopowders are homogenized at a ratio of up to 99:1 ZnO to refractory metal using a ultrasonic mixing process where the two powders are stirred in a container submerged in an ultrasonic bath. The ultrasonication prevents particle agglomeration during mixing. Following the ultrasonication the nanopowders are removed from the ultrasonic bath and are ready for use.

If a ternary band gap engineered alloy is to be employed, it is added at this step in the correct proportion if using a single deposition source. If using a bandgap engineered as opposed to undoped ZnO, it is best to separately create a bandgap engineered precursor which is devoid of zinc oxide yet is still mixed with the refined refractory metal powder. Due to the different sublimation rates of the bandgap engineered material with respect to the original ZnO material, obtaining fine dopant control is more difficult. A co-deposition technique is thereby employed to deposit both materials with independent control over the heating of each sample and thereby the dopant density in the final product.

The powders are then cold pressed using a standard pellet pressing technique to produce ZnO/Refractory metal pellets suitable for placing in the thermal evaporation unit.

Although the present invention has been described in considerable detail with reference to certain preferred versions thereof, other versions are possible. Therefore, the spirit and scope of the appended claims should not be limited to the description of the preferred versions contained herein. All features disclosed in this specification may be replaced by alternative features serving the same, equivalent or similar purpose, unless expressly stated otherwise. Thus, unless expressly stated otherwise, each feature disclosed is one example only of a generic series of equivalent or similar features.

### OBJECTS OF THE INVENTION

1 A method for producing stable metal oxide semiconductor materials exhibiting p-type characteristics for over 24 months under atmospheric conditions. The metal oxide system is exemplified by zinc oxide, or ternary alloys with zinc oxide such as MgZnO, CdZnO, GaZnO, etc. as well as other metal oxide semiconductors such as GaO. MgO, CuO, etc.
2 A method for depositing the stable p-type zinc oxide semiconductor described in 1 utilizing physical vapor deposition.
3 The method described in object 2 which utilizes a zinc oxide nanopowder and refractory metal nanopowder intimately mixed and homogenized. When heated for deposition, the refractory metal scavenges oxygen from the zinc oxide producing a refractory metal oxide which does not incorporate or alloy into the zinc oxide being deposited. The scavenging action removes oxygen from the deposited zinc oxide without producing zinc interstitials or other dislocations in the crystalline structure. This material results in stable p-type zinc oxide.
4 A method for depositing stable p-type zinc oxide semiconductor material described in 1 utilizing LPRD metal organic chemical vapor deposition in a continuous flow regime.
5 A method described in object 4 where a refractory metal organic precursor is flowed simultaneously with a zinc metal organic precursor and an oxygen precursor. The refractory metal precursor scavenges oxygen from the deposition layer of the zinc precursor and oxygen precursor prior to deposition on the substrate forming an insoluble refractory metal oxide which does not alloy into the zinc oxide semiconductor layer being deposited. The refractory metal oxide spalls from the deposition surface preventing inclusion into the zinc oxide resulting in an oxygen deficient zinc oxide which does not have a significant quantity of other defects resulting in a stable p-type material.
6 A method for depositing stable p-type zinc oxide semiconductor material described in 1 utilizing LPRD metal organic chemical vapor deposition in a pulsed flow regime.
7 A method described in object 6 where a refractory metal organic precursor is pulsed in an alternating fashion with a zinc metal organic precursor and an oxygen precursor. The zinc and oxygen precursors deposit layers of zinc oxide material, 3-250 atom layers thick, onto the substrate. Next the refractory metal precursor is pulsed on while pulsing off the oxygen and zinc metal organic precursor. The refractory metal scavenges oxygen from the deposition layer of the zinc oxide, taking advantage of the oxygen mobility in the sample at the elevated growth temperature. The refractory metal forms an insoluble refractory metal oxide prior to adhesion on the substrate that does not alloy into the zinc oxide semiconductor layer being deposited. The refractory metal oxide spalls from the deposition surface preventing inclusion into the zinc oxide resulting in an oxygen deficient zinc oxide which does not have a significant quantity of other defects resulting in a stable p-type material.
8 A method for producing stable zinc oxide exhibiting strong p-type characteristics (p+ layer) which are stable for over 24 months under atmospheric conditions.
9 A method for depositing the stable p+-type zinc oxide semiconductor described in 8 utilizing physical vapor deposition. This material possesses a higher concentration of holes per unit volume than that of standard p-type material. This enhances the semiconductor characteristics and produces a better surface for applying a p-type electrical contact metal.
10 The method described in object 2 to produce p+ material which utilizes a zinc oxide powder and refractory metal intimately mixed and homogenized consisting of nanopowders of zinc oxide and refractory metal. Here the ratio of zinc oxide and refractory metal contains a slightly higher concentration to (1-2 percent increase over the ratio described in object 3) of refractory metal with respect to the zinc oxide material. When heated for deposition, the refractory metal scavenges oxygen from the zinc oxide producing a refractory metal oxide which does not incorporate or alloy into the zinc oxide being deposited. The scavenging action removes oxygen from the deposited zinc oxide without producing zinc interstitials or other dislocations in the crystalline structure. This material results in stable p-type zinc oxide.
11 A method for depositing stable p+-type zinc oxide semiconductor material described in 8 utilizing LPRD metal organic chemical vapor deposition in a continuous flow regime.
12 A method described in object 11 to produce stable p+ material where a refractory metal organic precursor is flowed simultaneously with a zinc metal organic precursor and an oxygen precursor. The refractory metal organic precursor is increased by 1-2 percent of that of the zinc and oxygen precursors described in object 5 which results in additional oxygen scavenging from the material. The refractory metal precursor scavenges oxygen from the deposition layer of the zinc precursor and oxygen precursor prior to deposition on the substrate forming an insoluble refractory metal oxide which does not alloy into the zinc oxide semiconductor layer being deposited. The refractory metal oxide spalls from the deposition surface preventing inclusion into the zinc oxide resulting in an oxygen deficient zinc oxide which does not have a significant quantity of other defects resulting in a p-type material.
13 A method for depositing stable p+-type zinc oxide semiconductor material described in 8 utilizing metal organic chemical vapor deposition in a pulsed flow regime.
14 A method described in object 6 where a refractory metal organic precursor is pulsed in an alternating fashion with a zinc metal organic precursor and an oxygen precursor. The zinc and oxygen precursors deposit layers of zinc oxide material, 3-250 atom layers thick, onto the substrate for growth. Next the refractory metal precursor is pulsed on while pulsing off the oxygen and zinc metal organic precursor. The duration of the refractory metal precursor is increased from that described in object 7 above to increase the hole concentration over that of p-type material. The refractory metal scavenges oxygen from the deposition layer of the zinc oxide layer, which is based on oxygen mobility in the sample at the elevated growth temperature. The refractory metal forms an oxide prior to adhesion on the substrate forming an insoluble refractory metal oxide which does not alloy into the zinc oxide semiconductor layer being deposited. The refractory metal oxide spalls from the deposition surface preventing inclusion into the zinc oxide resulting in an oxygen deficient zinc oxide which does not have a significant quantity of other defects resulting in a stable p-type material.
15 A capping layer is subsequently deposited over the p+ layer to protect the p+ layer from oxygen ingress which is achieved through alloying an oxygen scavenger metal layer which caps and seals the p+ layer preventing damage to the p+ layer. The transition between p and p+ layer can be discrete or smoothly continuous.

1. A method for producing stable zinc oxide based semiconductor materials exhibiting p-type characteristics, said method comprising the steps of:
providing a substrate material to receive deposition of a p-type zinc oxide material;
cleaning said substrate by removing excess oxygen from a surface of said substrate material;
placing said substrate material in a chemical vapor deposition chamber;
mounting said substrate material above a p-type zinc oxide precursor;
providing a heating device below said mounted substrate material;
placing p-type zinc oxide precursor material in said heating device and heating said p-type precursor zinc oxide material to remove excess oxygen;
continuing to heat p-type zinc oxide precursor material until sublimation of said p-type zinc oxide precursor material occurs;
providing and heating an oxygen scavenger refractory metal material until sublimation of said oxygen scavenger material occurs to remove excess oxygen from said p-type zinc oxide precursor,
depositing zinc oxide material onto said substrate material.

2. The method set forth in claim 1 wherein said step of cleaning said substrate material is selected from the group of ultrasonic cleaning, reactive ion-etching, plasma enhanced ion etching, acid etching, plasma cleaning using O₂, Ar, CH₂, C₂H₂, CF₄, CF₃H, or the like; plasma ashing/etching; ion milling, glancing angle ion milling, mechanical lapping and polishing, rapid thermal annealing in reactive or inert atmosphere, and rapid thermal annealing in a hydrogen or vacuum atmosphere.

3. The method set forth in claim 1, wherein said substrate material is selected from the group consisting of Zinc Oxide (ZnO), gallium nitride (GaN), Boron Nitride (BN), Aluminum Nitride (AlN), Gallium Phosphide (GaP), Gallium Arsenide (GaAs), Gallium Antimonide (GaSb), Indium Nitride (InN), Indium Phosphide (InP), Indium Arsenide (InAs), Cadmium Sulfide (CdS), Zinc Sulfide (ZnS), Titanium Oxide (TiO₂), Cupric Oxide (CuO, Cu2O), Uranium oxide (UO₂) sapphire (Al₂O₃), quartz (SiO₂), gallium oxide (GaO), organic semiconductor materials (PEDOT, Anthracene, pentacene), Indium Tin Oxide (ITO), and Silicon Carbide (SiC).

4. The method set forth in claim 1, further including the step of rotating said substrate material within said vapor deposition chamber.

5. The method set forth in claim 1, further including the step of subsequently changing a ratio of the quantity of sublimating zinc oxide with respect to that of the refractory metal material in order to remove a greater quantity of excess oxygen from said p-type zinc oxide precursor.

6. The method set forth in claim 1, further including the step of depositing an oxygen scavenging layer on an outer surface of said coated substrate.

7. The method set forth in claim 6, wherein said oxygen scavenging layer is formed from a refractory metal selected from the group consisting of calcium, tungsten, strontium, erbium, aluminum, titanium, uranium, and thorium.

8. The method set forth in claim 7, further including the step of capping said oxygen scavenging layer with a protective noble metal layer by depositing said noble metal layer over said oxygen scavenging layer within said chemical vapor deposition chamber.

9. A method for producing stable zinc oxide based semiconductor materials exhibiting p-type characteristics, said method comprising the steps of:
providing a substrate material to receive deposition of a p-type zinc oxide material;
cleaning said substrate by removing excess oxygen from a surface of said substrate material;
placing said substrate material in a chemical vapor deposition chamber;
heating said substrate material;
providing a zinc precursor, an oxygen precursor and a refractory metal precursor, each said precursor in gas form;
providing a flow of said precursor gas, wherein said precursor gas flows across said substrate material in a measured, fixed ratio between zinc precursor, oxygen precursor and refractory metal precursor.

10. The method set forth in claim 9, further including the step of subsequently changing said precursor gas ratio by increasing an amount of said refractory metal precursor, and decreasing an amount of said oxygen precursor, and allowing precursor gas flow to continue over said substrate.

11. The method set forth in claim 9, further including the step of depositing an oxygen scavenging layer on an outer surface of said coated substrate.

12. The method set forth in claim 11, wherein said oxygen scavenging layer is formed from a refractory metal selected from the group consisting of calcium, tungsten, strontium, erbium, aluminum, titanium, uranium, and thorium.

13. The method set forth in claim 12, further including the step of capping said oxygen scavenging layer with a protective noble metal layer by depositing said noble metal layer over said oxygen scavenging layer within said chemical vapor deposition chamber.

14. The method set forth in claim 9, further including the step of rotating said substrate material within said chemical vapor deposition chamber.

15. A method for producing stable zinc oxide based semiconductor materials exhibiting p-type characteristics, said method comprising the steps of:
providing a substrate material to receive deposition of a p-type zinc oxide material;
cleaning said substrate by removing excess oxygen from a surface of said substrate material;
placing said substrate material in a chemical vapor deposition chamber;
heating substrate;
providing a zinc precursor, an oxygen precursor and a refractory metal precursor in gas form;
providing a pulse flow of said zinc and oxygen precursor in a fixed ratio;
stopping said pulse flow of zinc and oxygen precursor and subsequently providing a pulse flow of refractory metal precursor;
alternating pulse flow of zinc and oxygen precursor with pulse flow of refractory metal precursor, wherein said precursor gases alternately flow across said substrate material in a fixed ratio between said zinc precursor, oxygen precursor and refractory metal precursor.

16. The method set forth in claim 15, further including the step of depositing an oxygen scavenging layer on an outer surface of said coated substrate.

17. The method set forth in claim 16, wherein said oxygen scavenging layer is formed from a refractory metal selected from the group consisting of calcium, tungsten, strontium, erbium, aluminum, titanium, uranium, and thorium.

18. The method set forth in claim 17, further including the step of capping said oxygen scavenging layer with a protective noble metal layer by depositing said noble metal layer over said oxygen scavenging layer within said chemical vapor deposition chamber.

19. The method set forth in claim 15 wherein said step of cleaning said substrate material is selected from the group of ultrasonic cleaning, reactive ion-etching, plasma enhanced ion etching, acid etching, plasma cleaning using O₂, Ar, CH₂, C₂H₂, CF₄, CF₃H, or the like; plasma ashing/etching; ion milling, glancing angle ion milling, mechanical lapping and polishing, rapid thermal annealing in reactive or inert atmosphere, and rapid thermal annealing in a hydrogen or vacuum atmosphere.

20. The method set forth in claim 15, wherein said substrate material is selected from the group consisting of Zinc Oxide (ZnO), gallium nitride (GaN), Boron Nitride (BN), Aluminum Nitride (AlN), Gallium Phosphide (GaP), Gallium Arsenide (GaAs), Gallium Antimonide (GaSb), Indium Nitride (InN), Indium Phosphide (InP), Indium Arsenide (InAs), Cadmium Sulfide (CdS), Zinc Sulfide (ZnS), Titanium Oxide (TiO₂), Cupric Oxide (CuO, Cu2O), Uranium oxide (UO₂) sapphire (Al₂O₃), quartz (SiO₂), gallium oxide (GaO), organic semiconductor materials (PEDOT, Anthracene, pentacene), Indium Tin Oxide (ITO), and Silicon Carbide (SiC).

21. The method set forth in claim 15, further including the step of rotating said substrate material within said chemical vapor deposition chamber.

22. The method set forth in claim 15, further including the step of subsequently changing the ratio of the pulse flow of said zinc and oxygen precursor in a fixed ratio with respect to that of the pulse flow of refractory metal precursor in order to remove a greater quantity of excess oxygen from said p-type zinc and oxygen precursor pulse.
